(19) United States
(12) Patent Application Publication
(10) Pub. No.: US 2012/0060909 A1
(43) Pub. Date: Mar. 15, 2012

(54) TRANSPARENT ELECTRODE SUBSTRATE AND PHOTOELECTRIC CONVERSION ELEMENT

(75) Inventors: Yoshihide Nagata, Tokyo (JP); Masaaki Sekine, Miyagi (JP); Yuto Takagi, Kanagawa (JP)

(73) Assignee: Sony Corporation, Tokyo (JP)

(21) Appl. No.: 13/087,543

(22) Filed: Apr. 15, 2011

(30) Foreign Application Priority Data
Apr. 23, 2010 (JP) 2010-099407

(51) Int. Cl. H01L 31/0224

(52) U.S. Cl. 136/256

(57) ABSTRACT

A transparent electrode substrate includes: a substrate having translucency; a base layer that is laminated on the substrate and includes a surface on which lattice-like grooves are formed; a lattice-like metal wiring layer that is formed by embedding a metallic material into the grooves; a conductive oxide layer that is laminated on the base layer such that the conductive oxide layer is electrically connected to the metal wiring layer, the conductive oxide layer being formed of a first transparent conducting oxide having a first specific resistance; and an inorganic protective layer that is laminated on the conductive oxide layer and formed of a second transparent conducting oxide having acid resistance and a second specific resistance larger than the first specific resistance.

### BACKGROUND OF THE INVENTION

1. Field of the Invention

The present invention relates to a transparent electrode substrate having a low resistance and corrosion resistance and a photoelectric conversion element including the transparent electrode substrate.

2. Description of the Related Art

In recent years, dye-sensitized solar cells as one of photoelectric conversion elements are being developed. A dye-sensitized solar cell includes a semiconductor layer that supports a pigment, a negative electrode that comes into contact with the semiconductor layer, an electrolyte, and a positive electrode opposing the semiconductor layer with the electrolyte interposed between the positive electrode and the electrolyte. The pigment emits electrons by light entering the semiconductor layer, and the emitted electrons are transported to the negative electrode via the semiconductor layer. The negative electrode and the positive electrode are connected to an external circuit, and the electrons that have reached the positive electrode via the external circuit are caused to return to the pigment by the electrolyte. By repeating such a cycle, electric energy can be extracted in the external circuit.

In the dye-sensitized solar cell, a system in which a negative electrode is formed by a transparent conductive film and sunlight is caused to enter a semiconductor layer from the negative electrode side is typically adopted (see, for example, Japanese Patent Application Laid-open No. 2004-146425; hereinafter, referred to as Patent Document 1). In this case, for efficiently extracting electrons emitted from a pigment, the negative electrode that is in contact with the semiconductor layer is required to have a high optical transmittance and low electrical resistance. On the other hand, for suppressing lowering of a temporal conversion efficiency, the constituent material of the negative electrode is required to have durability with respect to an electrolytic solution.

In this regard, Patent Document 1 discloses an electrode substrate including a metal wiring layer formed along a wiring pattern formed with a groove on a transparent substrate, and a transparent electrode layer that is electrically connected to the metal wiring layer and has corrosion resistance. Accordingly, transparency, low resistance characteristics, and corrosion resistance of the electrode substrate can be obtained.

### SUMMARY OF THE INVENTION

However, since the electrode substrate disclosed in Patent Document 1 is formed by directing processing the grooves on a surface of the transparent substrate and forming a metal layer in the grooves, there is a need to select an appropriate substrate material for groove processing, which is problematic in that usable materials are limited. In addition, since laser and etching techniques are used for groove processing, there is also a problem that there is a limit to an enhancement of a production efficiency.

In view of the circumstances as described above, there is a need for a transparent electrode substrate that has low resistance characteristics and corrosion resistance and is capable of enhancing a degree of freedom in selecting materials and productivity as well.

According to an embodiment of the present invention, there is provided a transparent electrode substrate including a substrate, a translucent base layer, a lattice-like metal wiring layer, a conductive oxide layer, and an inorganic protective layer.

The substrate has translucency.

The translucent base layer is laminated on the substrate and includes a surface on which lattice-like grooves are formed.

The lattice-like metal wiring layer is formed by embedding a metallic material into the grooves.

The conductive oxide layer is laminated on the base layer such that the conductive oxide layer is electrically connected to the metal wiring layer, the conductive oxide layer being formed of a first transparent conducting oxide having a first specific resistance.

The inorganic protective layer is laminated on the conductive oxide layer and formed of a second transparent conducting oxide having acid resistance and a second specific resistance larger than the first specific resistance.

Further, since the transparent electrode substrate includes the metal wiring layer having a smaller specific resistance than the conductive oxide layer, a surface resistance can be made smaller than that of the conductive oxide layer alone. Moreover, since the metal wiring layer is formed in a lattice, lowering of an optical transparency can be suppressed. Accordingly, a transparent electrode substrate having a low resistance and an excellent optical transparency can be obtained. Furthermore, the conductive oxide layer is covered by the inorganic protective layer. As a result, it is possible to prevent the metal wiring layer and the conductive oxide layer from being oxidized and thus obtain a transparent electrode substrate that is also provided with corrosion resistance.

Moreover, in the transparent electrode substrate, the base layer having the lattice-like grooves for forming the metal wiring layer is structurally different from the substrate. Therefore, since there is no need to directly perform groove processing on the substrate, it becomes possible to form the substrate with a material that is excellent as a material or has excellent optical characteristics but an unfavorable property for it to be subjected to processing. Moreover, since the base layer only needs to have translucency and a shaping property, the groove processing becomes easy by using a material with a particularly high processability, with the result that productivity can be improved. Accordingly, a transparent electrode substrate that has a high degree of freedom in selecting a material to be used for the substrate and excellent productivity can be obtained.

The base layer may be formed of an ultraviolet-curable resin. With this structure, a fine groove configuration can be easily transferred. In addition, it can also be easily applied to a continuous production of a base layer that uses a roll-to-roll method. Moreover, since the ultraviolet-curable resin has an excellent optical transparency and high adhesiveness with respect to the substrate and the metal wiring layer, a high-quality transparent electrode substrate can be structured.

The metal wiring layer may have a thickness that is equal to or smaller than a depth of the grooves. With this structure, circumferences of the metal wiring layer can be positively covered by side walls of the grooves, with the result that a cover property of the metal wiring layer can be enhanced.

The transparent electrode substrate may further include an organic protective layer. The organic protective layer is interposed between the base layer and the conductive oxide layer, formed of a resin material having translucency, and convers the metal wiring layer.

With this structure, it is possible to enhance an anticorrosion property of the metal wiring layer and maintain low resistance characteristics of the transparent electrode substrate for a long period of time.

The second transparent conducting oxide may be an oxide having a specific resistance of 1*10⁶ Ω*cm or less.

With this structure, it is possible to easily lower the resistance of the conductive oxide layer and suppress an increase of a sheet resistance of the entire electrode.

The metal wiring layer may have a sheet resistance of 0.3Ω/□ or less. In this case, the lattice includes stripes and meshes.

With this structure, a transparent electrode substrate having a low resistance and excellent transparency can be obtained.

According to an embodiment of the present invention, there is provided a photoelectric conversion element including a transparent electrode substrate, an oxide semiconductor layer, an opposite electrode, and an electrolyte layer.

The transparent electrode substrate includes a substrate, a translucent base layer, a lattice-like metal wiring layer, a conductive oxide layer, and an inorganic protective layer. The substrate has translucency. The translucent base layer is laminated on the substrate and includes a surface on which lattice-like grooves are formed. The lattice-like metal wiring layer is formed by embedding a metallic material into the grooves. The conductive oxide layer is laminated on the base layer such that the conductive oxide layer is electrically connected to the metal wiring layer, the conductive oxide layer being formed of a first transparent conducting oxide having a first specific resistance. The inorganic protective layer is laminated on the conductive oxide layer and formed of a second transparent conducting oxide having acid resistance and a second specific resistance larger than the first specific resistance.

The oxide semiconductor layer is in contact with the inorganic protective layer and supports a photosensitized pigment.

The electrolyte layer is interposed between the oxide semiconductor layer and the opposite electrode.

In the photoelectric conversion element, the transparent electrode substrate includes the metal wiring layer that has a specific resistance smaller than the conductive oxide layer. Therefore, a surface resistance can be made smaller than that of the conductive oxide layer alone. Moreover, since the metal wiring layer is formed in a lattice, lowering of an optical transparency can be suppressed. As a result, an incident photon-to-current conversion efficiency can be improved. Furthermore, since the conductive oxide layer is covered by the inorganic protective layer, it is possible to prevent the metal wiring layer and the conductive oxide layer from being corroded due to an in-contact state with the electrolyte layer and enhance durability. According to the photoelectric conversion element, the base layer having the lattice-like grooves for forming the metal wiring layer has a different structure from the substrate. As a result, a degree of freedom in selecting a material to be used for the substrate is high, and productivity can be improved.

According to the embodiments of the present invention, a degree of freedom in selecting a material and productivity can be improved while also providing low resistance characteristics and corrosion resistance.

These and other objects, features and advantages of the present invention will become more apparent in light of the following detailed description of best mode embodiments thereof, as illustrated in the accompanying drawings.

### BRIEF DESCRIPTION OF DRAWINGS

FIG. 1 is a schematic cross-sectional diagram showing a photoelectric conversion element including a transparent electrode substrate according to a first embodiment of the present invention;

FIG. 2 is an enlarged cross-sectional diagram showing a main portion of the transparent electrode substrate;

FIG. 3 is a schematic perspective view of a metal wiring layer in the transparent electrode substrate;

FIG. 4 are schematic perspective views of main processes for explaining a production method of the transparent electrode substrate;

FIG. 5 is an enlarged diagram of a main portion for explaining one operation of the transparent electrode substrate;

FIG. 6 is an enlarged diagram of a main portion of a transparent electrode substrate according to a second embodiment of the present invention;

FIG. 7 is a diagram showing an example of a relationship between a maximum allowable thickness of an organic protective layer and an allowable power loss of an element according to an embodiment of the present invention; and

FIG. 8 is an enlarged diagram of a main portion of a transparent electrode substrate according to a third embodiment of the present invention.

### DESCRIPTION OF PREFERRED EMBODIMENTS

Hereinafter, embodiments of the present invention will be described with reference to the drawings.

### First Embodiment

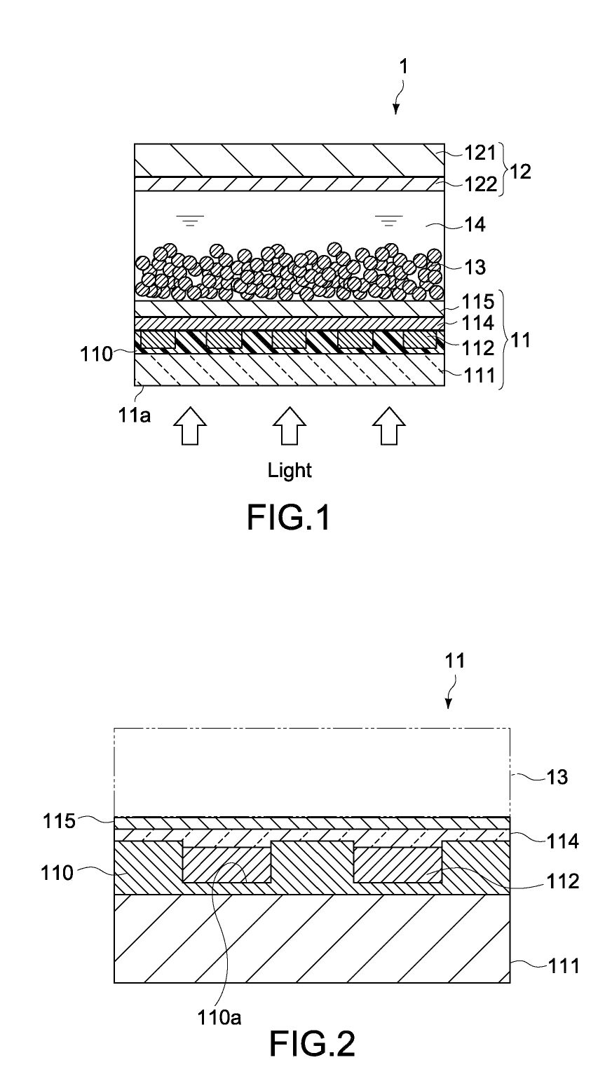

FIG. 1 is a schematic cross-sectional diagram of a photoelectric conversion element according to a first embodiment of the present invention. Hereinafter, a photoelectric conversion element 1 of this embodiment will be described.

The photoelectric conversion element 1 of this embodiment is constituted of a dye-sensitized solar cell. The photoelectric conversion element 1 includes a transparent electrode substrate 11 including a collective electrode (negative electrode), an opposite substrate 12 including an opposite electrode (positive electrode), an oxide semiconductor layer 13, and an electrolyte layer 14. The transparent electrode substrate 11 and the opposite substrate 12 are connected to a negative electrode and a positive electrode of an external circuit (load) (not shown). The oxide semiconductor layer 13 is formed of a porous titanium oxide formed on the transparent electrode substrate 11. The oxide semiconductor layer 13 supports a pigment whose electrons are excited by visible light irradiated onto the pigment, for example. The electrolyte layer 14 is interposed between the oxide semiconductor layer 13 and the opposite substrate 12 and formed of an oxidation-reduction material constituted of a combination of, for example, metallic iodide and iodine.

The transparent electrode substrate 11 is constituted of a transparent substrate 111 (first substrate) having a light incident surface 11a that external light such as sunlight enters and various electrode layers laminated on the other side of the light incident surface 11a. Details of the structure of the transparent electrode substrate 11 will be described later.

On the other hand, the opposite substrate 12 includes a substrate 121 (second substrate) and an electrode layer 122 formed on the substrate 121. The opposite substrate 12 is opposed to the transparent electrode substrate 11 with the electrode layer 122 facing an electrolyte layer 14. The constituent material of the substrate 121 is not particularly limited, and the substrate 121 may be an optically-transparent substrate or an opaque substrate. Though the electrode layer 122 is constituted of, for example, a metal layer, conductive materials other than metal may be used instead. A catalyst layer that makes it easier to supply electrons to the electrolyte layer 14 may be formed in the electrode layer 122.

### (Transparent Electrode Substrate)

Next, the transparent electrode substrate 11 will be described specifically. FIG. 2 is an enlarged cross-sectional diagram of the transparent electrode substrate 11.

The transparent electrode substrate 11 includes the transparent substrate 111 described above, a base layer 110, a metal wiring layer 112, a conductive oxide layer 114, and an inorganic protective layer 115.

The transparent substrate 111 is formed of a resin film having optical transparency, such as PET (polyethylene terephthalate), PEN (polyethylene naphthalate), and PC (polycarbonate), a glass substrate, or the like.

The base layer 110 is laminated on a surface (surface on other side of light incident surface 11a) of the transparent substrate 111. The base layer 110 has translucency and has lattice-like grooves 110a formed on the surface thereof. The lattice-like configuration includes stripes in which a plurality of linear patterns are formed in parallel in a uniaxial direction, meshes in which a plurality of linear patterns are formed in parallel in biaxial directions intersecting each other, and the like.

A method of forming the grooves 110a on the base layer 110 is not particularly limited, and a configuration transfer method that uses a die or a resin die is applicable. In this embodiment, an ultraviolet-curable resin is applied onto a die in which convex patterns corresponding to the grooves 110a are formed. After that, the ultraviolet-curable resin is cured and peeled off from the die, with the result that the base layer 110 is formed. Accordingly, the minutely-configured grooves 110a can be formed with high accuracy. Moreover, this method is also applicable to a continuous production of a base layer that uses a roll-to-roll method. Further, the ultraviolet-curable resin has an excellent optical transparency and high adhesiveness with respect to the substrate and the metal wiring layer. As a result, a high-quality transparent electrode substrate can be structured.

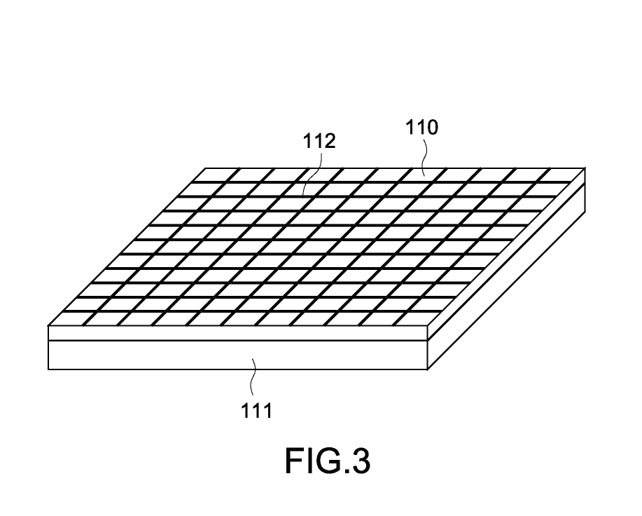

The metal wiring layer 112 is formed of a metallic material such as silver (Ag), copper (Cu), and aluminum and formed of Ag in this embodiment. The metal wiring layer 112 is embedded in the grooves on the surface of the base layer 110. Therefore, the wiring patterns on the metal wiring layer 112 are determined based on the formation patterns of the grooves 110a of the base layer 110. Although the metal wiring layer 112 formed in stripes is advantageous in view of optical transmittance, the metal wiring layer 112 in meshes has an advantage that an electrical conductivity can be secured even when the wiring is partially disconnected. In this embodiment, the metal wiring layer 112 is formed in meshes, the state of which is schematically shown in FIG. 3.

For forming the metal wiring layer 112, in addition to various printing methods such as screen printing and gravure printing, a silver salt diffusion transfer development method, a pattern plating method, a pattern etching method, and the like can be used. The thickness, line width, and pitch of the metal wiring layer 112 are not particularly limited, but since those values affect an aperture ratio of the transparent electrode substrate 11, the values are set as appropriate so that desired optical transmittance can be obtained. For example, the metal wiring layer 112 can be set such that the thickness is 0.1 to 50 μm, the line width is 10 to 100 μm, and the pitch is 100 to 1000 μm.

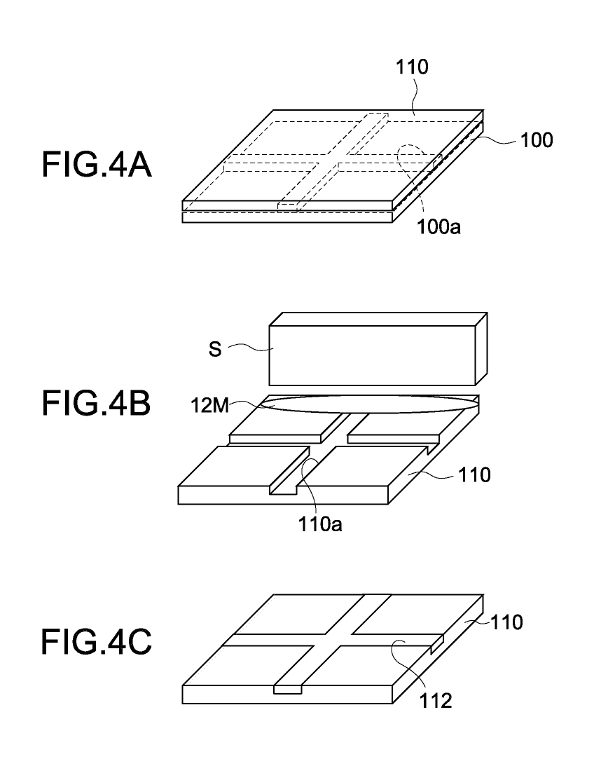

FIG. 4 are schematic perspective views of a main portion for showing an example of the steps of forming the base layer 110 and the metal wiring layer 112. As shown in FIG. 4A, the base layer 110 including the lattice-like grooves 110a corresponding to a convex pattern 100a is formed. Next, by embedding a paste-type metallic material 12M in the grooves 110a of the base layer 110 using a squeegee S as shown in FIG. 4B, the metal wiring layer 112 shown in FIG. 4C is formed on the base layer 110.

Since the metal wiring layer 112 is formed for reducing a sheet resistance of the transparent electrode substrate 11, a specific resistance, thickness, line width, pitch, and the like thereof are set so that a desired sheet resistance can be obtained. The sheet resistance of the metal wiring layer 112 alone can be set to be 0.3Ω/□ or less. Accordingly, it can cope with an increase in an area of the photoelectric conversion element while maintaining a predetermined conversion efficiency.

In this embodiment, the thickness of the metal wiring layer 112 is set to be equal to or smaller than the depth of the grooves 110a. With this structure, the circumferences of the metal wiring layer can be positively covered by the side walls of the grooves 110a, and the metal wiring layer 112 can be prevented from protruding from the surface of the base layer 110. As a result, a cover property of the conductive oxide layer 114 with respect to the base layer 110 and the metal wiring layer 112 can be enhanced.

The conductive oxide layer 114 is formed of a transparent conducting oxide and formed of ITO in this embodiment. In addition to ITO, other transparent conducting oxides such as SnO and ZnO are applicable. Accordingly, it becomes possible to easily realize a low resistance of an electron capture layer as a collective electrode. Furthermore, AZO, GZO, IZO, IGZO, and the like that are doped with aluminum, gallium, indium, and the like may be used as a ZnO-based transparent conducting oxide.

The specific resistance of the conductive oxide layer 114 is smaller the better in view of the incident photon-to-current conversion efficiency of the photoelectric conversion element 1. In this embodiment, the conductive oxide layer 114 has a specific resistance of, for example, 5*10⁻³ Ω*cm or less. The thickness of the conductive oxide layer 114 is not particularly limited and is, for example, 10 to 1000 nm.

The thickness of the conductive oxide layer 114 can be set in consideration of the line width and pitch of the metal wiring layer 112, an allowable power loss of the element, and the like. In other words, electrons trapped at openings in areas other than right above the wirings of the metal wiring layer 112 move through the conductive oxide layer 114 to positions right above the nearest wiring. Therefore, a large resistance of the conductive oxide layer 114 inhibits the flow of the electrons to thus cause a power loss. In this regard, a necessary layer thickness of the conductive oxide layer 114 can be calculated by determining the specific resistance of the conductive oxide layer 114.

The conductive oxide layer 114 is formed by a sputtering method. However, the method is not limited thereto, and a vacuum vapor deposition method, a CVD method, a wet coating method, and the like may be adopted instead.

The inorganic protective layer 115 is formed of a transparent conducting oxide and laminated on the conductive oxide layer 114. The inorganic protective layer 115 has a function as a protective layer for protecting the conductive oxide layer 114 from a corrosion due to the conductive oxide layer 114 coming into contact with the electrolyte layer 14. Therefore, the inorganic protective layer 115 is formed of a transparent conducting oxide having acid resistance. In this embodiment, the inorganic protective layer 115 is formed of a transparent conducting oxide including a titanium oxide (TiOx).

The inorganic protective layer 115 is electrically connected to the oxide semiconductor layer 13. The inorganic protective layer 115 is constituted of a denser film than the oxide semiconductor layer 13. Accordingly, contact interfaces between the oxide semiconductor layer 13 and the transparent electrode substrate 11 are formed of the same type of semiconductor material. As a result, electron conductance bands among the layers are approximated, and an electron transportation efficiency from the oxide semiconductor layer 13 to the transparent electrode substrate 11 is promoted, thus leading to an increase of the incident photon-to-current conversion efficiency.

Here, the transparent conducting oxide that forms the inorganic protective layer 115 may include other metallic oxides instead of or in addition to a titanium oxide. Examples of other metallic oxides include one or two or more types of oxides of zirconium (Zr), niobium (Nb), cerium (Ce), tungsten (W), silicon (Si), aluminum (Al), tin (Sn), zinc (Zn), magnesium (Mg), bismuth (Bi), manganese (Mn), yttrium (Y), tantalum (Ta), lanthanum (La), and strontium (Sr).

The inorganic protective layer 115 has a specific resistance (second specific resistance) that is equal to or larger than the specific resistance of the conductive oxide layer 114 (first specific resistance). As described above, the inorganic protective layer 115 is formed of a transparent conducting oxide having a higher resistance than the conductive oxide layer 114. The specific resistance of the inorganic protective layer 115 is 1*10⁶ Ω*cm or less. Accordingly, an increase of the resistance of the transparent electrode substrate 11 can be suppressed.

In general, the specific resistance of the transparent conducting oxide such as a titanium oxide varies depending on a valence of oxygen (oxidation degree). Therefore, by adjusting the valence of oxygen, the specific resistance of the inorganic protective layer 115 can be controlled.

Though the inorganic protective layer 115 is formed by a sputtering method, the method is not limited thereto, and a vacuum vapor deposition method, a CVD method, a wet coating method, and the like may be adopted instead.

The thickness of the inorganic protective layer 115 is, for example, 5 nm or more and 500 nm or less. With a thickness smaller than 5 nm, the acid resistance of the inorganic protective layer 115 becomes difficult to be secured. Further, with a thickness exceeding 500 nm, there is a fear that the optical transmittance of the transparent electrode substrate 11 may decrease.

The transmittance of the transparent electrode substrate 11 with respect to visible light is higher the better in view of the incident photon-to-current conversion efficiency of the photoelectric conversion element 1. In this embodiment, the transparent electrode substrate 11 has a visible light transmittance of 70% or more. The thickness of each of the conductive oxide layer 114 and the inorganic protective layer 115 is set as appropriate so that the high transmittance characteristics described above can be obtained.

### (Operation of Photoelectric Conversion Element)

In the photoelectric conversion element 1 of this embodiment, light such as sunlight and artificial light enters the oxide semiconductor layer 13 from the transparent electrode substrate 11 side. When the oxide semiconductor layer 13 is irradiated with light, electrons in the pigment transit from a basal state to an excited state to be emitted from the pigment. The oxide semiconductor layer 13 transports the electrons emitted from the pigment to the transparent electrode substrate 11 so that the electrons are supplied to the external circuit from the transparent electrode substrate 11. The electrons that have passed the external circuit are transported to the electrode layer 122 of the opposite substrate 12 and returned to the pigment on the oxide semiconductor layer 13 after undergoing an oxidation-reduction reaction with the electrolyte layer 14. By repeating such a cycle, electric energy is extracted in the external circuit.

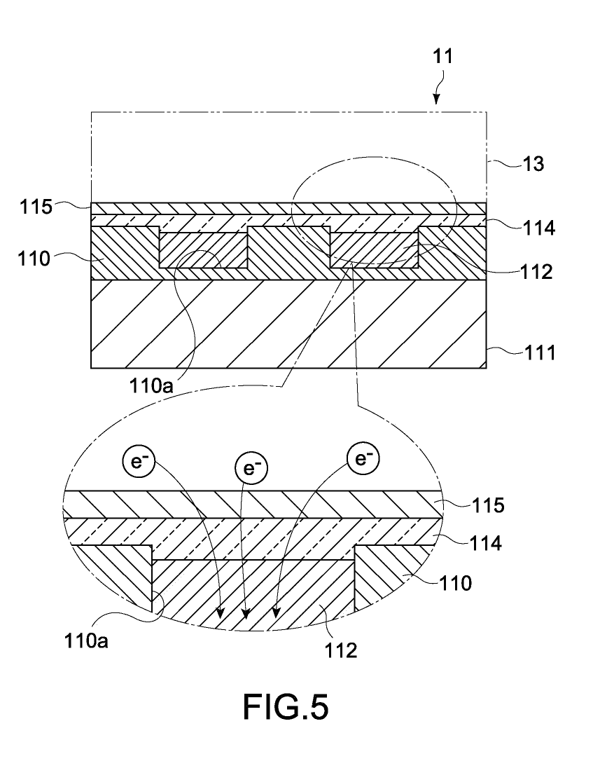

FIG. 5 is a cross-sectional diagram schematically showing a state where electrons flow in the transparent electrode substrate 11. The oxide semiconductor layer 13 irradiated with incident light transports, via the inorganic protective layer 115, the electrons emitted from the pigment to the conductive oxide layer 114 having a lower resistance than the inorganic protective layer 115. At least partial electrons transported to the conductive oxide layer 114 are additionally transported from the conductive oxide layer 114 to the metal wiring layer 112 having a lower resistance than the conductive oxide layer 114. As a result, the electrons transported to the transparent electrode substrate 11 are supplied to the external circuit via the conductive oxide layer 114 and the metal wiring layer 112.

As described above, since the photoelectric conversion element 1 of this embodiment includes the metal wiring layer 112 having a lower resistance than the conductive oxide layer 114, a surface resistance can be made smaller than that of the conductive oxide layer alone. Moreover, since the metal wiring layer 112 is formed in a lattice, lowering of an optical transparency can be suppressed. As a result, the photoelectric conversion element 1 having a low resistance and an excellent optical transparency can be obtained. In addition, the incident photon-to-current conversion efficiency of the photoelectric conversion element 1 can be enhanced.

Here, the inorganic protective layer 115 is formed of a transparent conducting oxide having a higher resistance than the conductive oxide layer 114. By setting the specific resistance of the inorganic protective layer 115 to be 1*10⁶ Ω*cm or less, an increase of a sheet resistance of the entire film can be suppressed, and the sheet resistance can be made about the same level as the sheet resistance of the conductive oxide layer 114 alone. Accordingly, because low resistance characteristics can be secured while maintaining the transparency of the transparent electrode substrate 11, lowering of the incident photon-to-current conversion efficiency can be avoided. Further, since the inorganic protective layer 115 is interposed between the conductive oxide layer 114 and the oxide semiconductor layer 13, a so-called reverse electron reaction in which electrons flow backward from the transparent electrode substrate 11 to the oxide semiconductor layer 13 can be effectively inhibited from occurring, and it is also possible to prevent a local battery from being formed. As a result, the inorganic protective layer 115 largely contributes to the enhancement of the incident photon-to-current conversion efficiency.

On the other hand, in this embodiment, the conductive oxide layer 114 is covered by the inorganic protective layer 115. Accordingly, the metal wiring layer 112 and the conductive oxide layer 114 can be prevented from being oxidized due to a corrosion of an electrolyte material, and a transparent electrode substrate and a photoelectric conversion element also having corrosion resistance can be obtained.

Moreover, in the transparent electrode substrate 11 of this embodiment, the base layer 110 having the lattice-like grooves 110a for forming the metal wiring layer 112 is structurally different from the transparent substrate 111. Therefore, since there is no need to directly perform groove processing on the transparent substrate 111, it becomes possible to form the transparent substrate 111 with a material that is excellent as a material or has excellent optical characteristics but an unfavorable property for it to be subjected to processing. Moreover, since the base layer 110 only needs to have translucency and a shaping property, the groove processing becomes easy by using a material with a particularly high processability, with the result that productivity can be improved. Accordingly, a transparent electrode substrate 11 that has a high degree of freedom in selecting a material to be used for the transparent substrate 111 and excellent productivity can be obtained.

### Second Embodiment

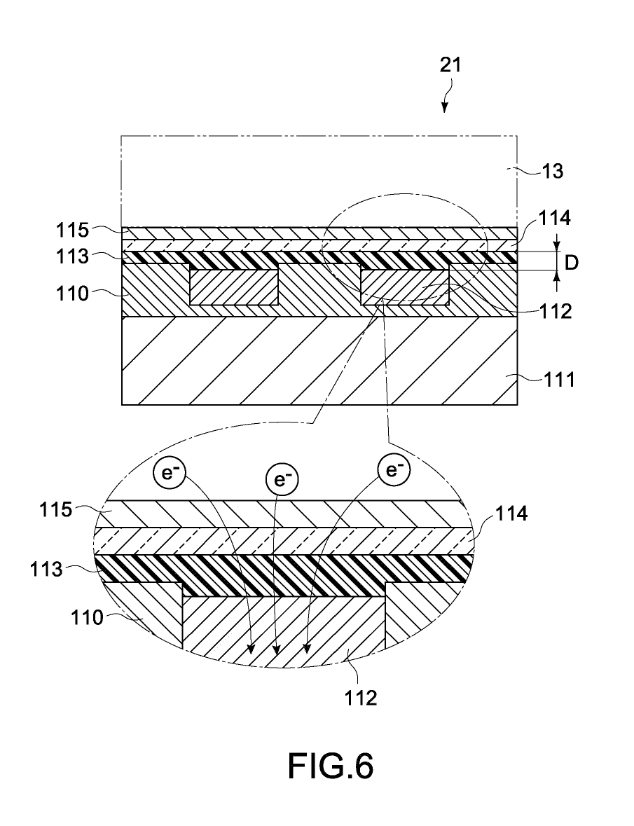

FIG. 6 shows a second embodiment of the present invention. It should be noted that portions that correspond to those of the first embodiment above in the figure are denoted by the same reference numerals, and detailed descriptions thereof will be omitted.

A transparent electrode substrate 21 of this embodiment differs from that of the above embodiment in that the transparent electrode substrate 21 includes an organic protective layer 113 between the base layer 110 and the conductive oxide layer 114. Since the organic protective layer 113 prevents the metal wiring layer 112 from being corroded due to the metal wiring layer 112 coming into contact with the electrolyte layer 14, the organic protective layer 113 is formed on the transparent substrate 111 so as to cover the metal wiring layer 112.

In this embodiment, the organic protective layer 113 is formed of a composite material in which conductive particles are mixed into a transparent resin. As the transparent resin, a resin material that is durable to materials such as iodine and iodide that constitute the electrolyte layer 14 is used. Although polyvinyl alcohol (PVA) is used as this type of resin material in this embodiment, other resins having an optical transparency such a polyester resin, an epoxy resin, and a phenol resin can also be used. Moreover, although conductive oxide particles such as ITO particles are used for the conductive particles, metal particles and the like may be used instead.

When using PVA for the transparent resin and an ITO filler for the conductive particles, for example, an organic protective layer having uniformly-dispersed conductive particles can be obtained by setting a weight mix ratio of the ITO filler to PVA to be 30% to 70%. The specific resistance at the time the weight mix ratio is 30% to 50% exceeds 100 Ω*cm, and the specific resistance at the time the weight mix ratio is 70% is 20 to 100 Ω*cm.

The specific resistance of the organic protective layer 113 is smaller the better. Accordingly, the supply of electrons from the conductive oxide layer 114 to the metal wiring layer 112 becomes simple, and the low-resistance transparent electrode substrate 11 can be realized. A thickness D (see FIG. 6) of the organic protective layer 113 interposed between the metal wiring layer 112 and the conductive oxide layer 114 is required to be at least enough to prevent an electrolyte material from entering the metal wiring layer 112. A maximum value of the thickness D is determined based on the magnitude of the specific resistance of the organic protective layer 113, and the maximum value of the thickness D can be set to become smaller as the specific resistance of the organic protective layer 113 becomes smaller.

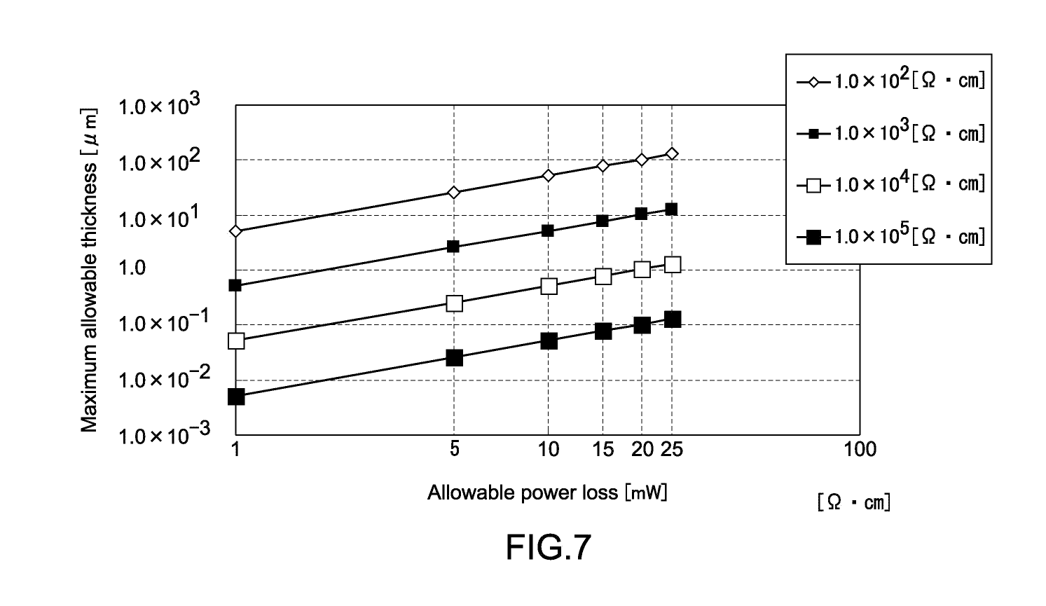

The maximum value of the thickness D of the organic protective layer 113 is set as appropriate based on the specific resistance of the protective layer, an allowable power loss (design value) of the photoelectric conversion element, and the like. FIG. 7 is a diagram showing a simulation result of a relationship between a maximum allowable thickness of the organic protective layer 113 and an allowable power loss of the photoelectric conversion element for each specific resistance of the organic protective layer 113. As shown in FIG. 7, the maximum allowable thickness can be made larger as the specific resistance of the material decreases, and the allowable power loss can be reduced at the same thickness. For example, when the allowable power loss is 5%, the thickness of the organic protective layer 113 having the specific resistance of 100 Ω*cm is, for example, 50 μm or less. The thickness D can be calculated from, for example, an SEM (Scanning Electron Microscope) image of a cross section, and the like.

The method of forming the organic protective layer 113 is not particularly limited, and various coating methods such as die coating, spin coating, and spray coating are applicable. Further, since spaces among the patterns can be made flat in the metal wiring layer 112 by forming the organic protective layer 113, the conductive oxide layer 114 can be stably formed on the organic protective layer 113.

Also in the transparent electrode substrate 21 of this embodiment, the organic protective layer 113 can be used as a negative electrode of the photoelectric conversion element (dye-sensitized solar cell). Referring to FIG. 6, the oxide semiconductor layer 13 irradiated with incident light transports, via the inorganic protective layer 115, the electrons emitted from the pigment to the conductive oxide layer 114 having a lower resistance than the inorganic protective layer 115. At least partial electrons transported to the conductive oxide layer 114 are additionally transported from the conductive oxide layer 114 to the metal wiring layer 112 having a lower resistance than the conductive oxide layer 114 via the organic protective layer 113. As a result, the electrons transported to the transparent electrode substrate 11 are supplied to the external circuit via the conductive oxide layer 114 and the metal wiring layer 112.

As described above, according to this embodiment, the same operational effect as the first embodiment above can be obtained. In particular, according to this embodiment, since the organic protective layer 113 has conductivity, electrons can be easily supplied from the conductive oxide layer 114 to the metal wiring layer 112. Accordingly, it becomes possible to maintain a low resistance of the substrate even when a covering thickness of the organic protective layer 113 with respect to the metal wiring layer 112 becomes large and enhance corrosion resistance of the metal wiring layer 112.

Further, in this embodiment, the metal wiring layer 112 is covered by the organic protective layer 113, and the conductive oxide layer 114 is covered by the inorganic protective layer 115. Accordingly, it becomes possible to prevent the metal wiring layer 112 and the conductive oxide layer 114 from being oxidized due to a corrosion of an electrolyte material and obtain a transparent electrode substrate and a photoelectric conversion element also having corrosion resistance.

Furthermore, by forming the metal wiring layer 112 in the grooves 110a of the base layer 110, circumferences of the metal wiring layer 112 are surrounded by the substrate 111. Accordingly, a cover property of the organic protective layer 113 with respect to the metal wiring layer 112 is enhanced, and the metal wiring layer 112 can be prevented from being corroded by the electrolyte material due to a covering failure of the organic protective layer 113.

Moreover, the thickness of the metal wiring layer 112 is set to be equal to or smaller than the depth of the grooves 110a. Accordingly, the circumferences of the metal wiring layer 112 can be positively covered by the side walls of the grooves 110a. As a result, a cover property of the organic protective layer 113 with respect to the metal wiring layer 112 can be enhanced.

### Third Embodiment

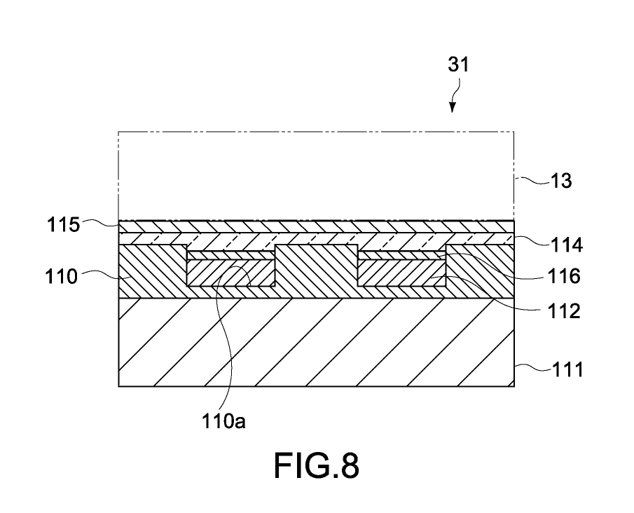

FIG. 8 is a partial cross-sectional diagram of a main portion of a transparent electrode substrate according to a third embodiment of the present invention. It should be noted that portions that correspond to those of the first embodiment above in the figure are denoted by the same reference numerals, and detailed descriptions thereof will be omitted.

A transparent electrode substrate 31 of this embodiment differs from that of the first embodiment above in that the transparent electrode substrate 31 includes a cover layer 116 that is interposed between the metal wiring layer 112 and the conductive oxide layer 114 and covers the metal wiring layer 112. The cover layer 116 has a function as an anticorrosion layer for protecting the metal wiring layer 112 from an electrolyte material.

The cover layer 116 is formed of a material having a higher level of corrosion resistance or acid resistance than the material constituting the metal wiring layer 112. The material is not particularly limited, and examples of the material include metal such as nickel, chrome, and tungsten, and oxides thereof. A specific resistance of the cover layer 116 is set to a value that is equal to or larger than the specific resistance of the metal wiring layer 112 and smaller than the specific resistance of the conductive oxide layer 114, for example. The method of forming the cover layer 116 is not particularly limited, and a plating method, a vacuum vapor deposition method, a sputtering method, a CVD method, and the like can be used.

According to this embodiment, since the metal wiring layer 112 is covered by the cover layer 116, the metal wiring layer 112 can be positively protected from degradation due to the metal wiring layer 112 coming into contact with the electrolyte material.

It should be noted that the cover layer 116 may be formed not only on the surface of the metal wiring layer 112 but also at a boundary portion between the metal wiring layer 112 and the grooves 110a. With this structure, an anticorrosion effect of the metal wiring layer 112 can be additionally enhanced. Moreover, the cover layer 116 is similarly applicable to the transparent electrode substrate 21 of the second embodiment above. In this case, the cover layer 116 is formed between the metal wiring layer 112 and the organic protective layer 113.

Heretofore, the embodiments of the present invention have been described. However, the present invention is not limited to those embodiments and can be variously modified based on the technical idea of the present invention.

For example, although the above embodiments have described the examples in which the present invention is applied to a transparent electrode substrate of a dye-sensitized solar cell (photoelectric conversion element), the present invention is not limited thereto and is also applicable to an electrode substrate in a resistance-film-type touch panel.

Furthermore, although a titanium oxide has been used for the oxide semiconductor layer 13 constituting the dye-sensitized solar cell in the above embodiments, a tin oxide, a tungsten oxide, a zinc oxide, a niobium oxide, and the like can also be used independently or in a combination of two or more.

The present application contains subject matter related to that disclosed in Japanese Priority Patent Application JP 2010-099407 filed in the Japan Patent Office on Apr. 23, 2010, the entire content of which is hereby incorporated by reference.

It should be understood by those skilled in the art that various modifications, combinations, sub-combinations and alterations may occur depending on design requirements and other factors insofar as they are within the scope of the appended claims or the equivalents thereof.

What is claimed is:

1. A transparent electrode substrate, comprising:
a substrate having translucency;
a translucent base layer that is laminated on the substrate and includes a surface on which lattice-like grooves are formed;
a lattice-like metal wiring layer that is formed by embedding a metallic material into the grooves;
a conductive oxide layer that is laminated on the base layer such that the conductive oxide layer is electrically connected to the metal wiring layer, the conductive oxide layer being formed of a first transparent conducting oxide having a first specific resistance; and
an inorganic protective layer that is laminated on the conductive oxide layer and formed of a second transparent conducting oxide having acid resistance and a second specific resistance larger than the first specific resistance.

2. The transparent electrode substrate according to claim 1,
wherein the base layer is formed of an ultraviolet-curable resin.

3. The transparent electrode substrate according to claim 1,
wherein the metal wiring layer has a thickness that is equal to or smaller than a depth of the grooves.

4. The transparent electrode substrate according to claim 1, further comprising
an organic protective layer that is interposed between the base layer and the conductive oxide layer, formed of a resin material having translucency, and covers the metal wiring layer.

5. The transparent electrode substrate according to claim 1,
wherein the second transparent conducting oxide is an oxide having a specific resistance of 1*10⁶ Ω*cm or less.

6. The transparent electrode substrate according to claim 1,
wherein the metal wiring layer has a sheet resistance of 0.3Ω/□ or less, and
wherein the lattice includes stripes and meshes.

7. The transparent electrode substrate according to claim 1, further comprising
a cover layer that is interposed between the metal wiring layer and the conductive oxide layer, formed of a material having stronger acid resistance than the metal wiring layer, and covers the metal wiring layer.

8. A photoelectric conversion element, comprising:
a transparent electrode substrate including
a substrate having translucency,
a translucent base layer that is laminated on the substrate and includes a surface on which lattice-like grooves are formed,
a lattice-like metal wiring layer that is formed by embedding a metallic material into the grooves,
a conductive oxide layer that is laminated on the base layer such that the conductive oxide layer is electrically connected to the metal wiring layer, the conductive oxide layer being formed of a first transparent conducting oxide having a first specific resistance, and
an inorganic protective layer that is laminated on the conductive oxide layer and formed of a second transparent conducting oxide having acid resistance and a second specific resistance larger than the first specific resistance;
an oxide semiconductor layer that is in contact with the inorganic protective layer and supports a photosensitized pigment;
an opposite electrode; and
an electrolyte layer interposed between the oxide semiconductor layer and the opposite electrode.
